(19) United States
(12) Patent Application Publication
(10) Pub. No.: US 2017/0062194 A1
(43) Pub. Date: Mar. 2, 2017

(54) SPUTTER TARGET FOR FORMING A LAYER OF A PERPENDICULAR RECORDING MEDIUM BY MAGNETRON SPUTTERING

(71) Applicant: Showa Denko HD Singapore Pte Ltd, Singapore (SG)

(72) Inventors: Ajeesh Mavolil SAHADEVAN, Ichihara City (JP); Amarendra Kumar SINGH, Singapore (SG); Kazunori KOYAMA, Singapore (SG)

(21) Appl. No.: 14/938,838

(22) Filed: Nov. 11, 2015

(30) Foreign Application Priority Data
Sep. 1, 2015 (SG) 10201506916U

(51) Int. Cl. H01J 37/34

(52) U.S. Cl. CPC H01J 37/3429; H01J 37/3405

(57) ABSTRACT

A sputter target for forming a layer of a perpendicular recording medium by magnetron sputtering, wherein material composition of the sputter target is varied along a radius of the sputter target from a centre of the sputter target to an outer diameter of the sputter target.

### CROSS REFERENCE TO RELATED APPLICATIONS

This application claims priority to Singapore Application No. SG 10201506916U filed with the Intellectual Property Office of Singapore on Sep. 1, 2015 and entitled “SPUTTER TARGET FOR FORMING A LAYER OF A PERPENDICULAR RECORDING MEDIUM BY MAGNETRON SPUTTERING”, which is incorporated herein by reference in its entirety for all purposes.

### FIELD

The present invention relates to a sputter target for forming a layer of a perpendicular recording medium by magnetron sputtering.

### BACKGROUND

Perpendicular recording media are widely used in various storage applications, both in commercial and personal storage solutions. In perpendicular magnetic recording media, bits are formed by a magnetic field in a direction that is perpendicular to the plane of a perpendicular recording medium having perpendicular magnetizing anisotropy with typically a layer of magnetic material on a suitable substrate. Very high linear recording densities are achieved by utilizing a “single-pole” magnetic transducer or “head” with such perpendicular magnetic media. Areal density capacity (ADC) is a figure of merit for magnetic recording media performance and in order to edge alternative storage technologies, persistent efforts are needed for further improvement.

To obtain higher ADC, a perpendicular recording medium with smaller grains, a recording layer with higher magnetic anisotropic material and better writability are needed. It is generally observed that parameters such as grain size, anisotropy and writability may vary along the radial direction of the recording medium. In a disc-shaped perpendicular recording medium, the read/write (R/W) parameters at an inner diameter (ID) zone, a middle diameter (MD) zone and an outer diameter (OD) zone of the perpendicular recording medium have differences owing to several reasons such as sputter process uniformity, head skew and data access rate, among others. For example, in a recording media, data access rate at the OD zone is higher compared to the ID zone due to higher linear velocity at the OD zone, and the outer diameter (OD) zone of the recording medium has the largest area while its areal density is lower than inner regions of the recording medium. Thus, a strategy is needed to take care of the recording performance at each zone of the recording medium, in particular at the OD zone.

Magnetron sputtering is a common deposition method used in the fabrication of magnetic recording media by which the magnetic recording layer is deposited onto a substrate by sputtering. The material of the magnetic recording layer that is to be sputtered or deposited is provided in the form of a disk referred to as a sputter target typically having a uniform material composition across its surface area and depth. However, in a magnetic recording medium, owing to the several reasons mentioned above, the R/W performance at different zones is different even when similar sputter target compositions are used. For example, in a 2.5 inch recording medium, bits per inch (BPI) can degrade by as high as 10% when moving from the MD zone to the OD zone. This is a result of the recording head skew and the higher linear velocity at the OD zone.

Currently, several strategies are used to control the parameters at different zones of the perpendicular recording medium. However, most of them focus on process control—for example, changing the sputter target magnetron spacing or sputter target shield spacing. These process control strategies help to control the thickness profile of the sputtered layers from the ID to the OD zone of the disk, which in turn controls the R/W parameters. Although controlling thickness of the sputtered layers at different zones of the magnetic recording disk or media helps to tune writability, it is still insufficient to close the gap of 10% difference in BPI between the MD and OD zones.

### SUMMARY OF INVENTION

The present disclosure presents an approach to control film properties in a perpendicular recording medium by providing a suitable magnetron sputter target with zone specific properties for sputter deposition of a layer having an inner diameter (ID) zone, a middle diameter (MD) zone and an outer diameter (OD) zone of the perpendicular recording medium. Different film properties are provided at different zones in order to take care of limitations associated with uniformity of the sputter process and read-write process. The current invention proposes a sputter process sputter target to match the needs of each zone of the recording medium.

According to a first aspect, there is provided a sputter target for forming a layer of a perpendicular recording medium by magnetron sputtering, wherein material composition of the sputter target is varied along a radius of the sputter target from a centre of the sputter target to an outer diameter of the sputter target.

Material composition of the sputter target may be varied by gradation of the material composition. Alternatively, material composition of the sputter target may be varied by providing a number of concentric regions in the sputter target wherein each concentric region has a different material composition from other concentric regions in the number of concentric regions.

The sputter target may have a diameter of 170 mm, a first region of the sputter target comprising its centre may extend to a radius of 40 mm, a second region adjacent to and beyond the first region may extend from a radius of 40 mm to 60 mm, and a remaining area of the sputter target beyond the second region forms a third region of the sputter target.

The layer may comprise a recording layer and the sputter target may comprise one of: a CoCrPtX-oxide and a CoCrPtX.

The sputter target may comprise the CoCrPtX-oxide and proportion of the oxide in the sputter target may range from 5% to 25%.

The proportion of the oxide may increase radially from a centre to an outer region of the sputter target. Alternatively, the proportion of the oxide may decrease radially from a centre to an outer region of the sputter target.

Ratio of Pt:Cr in the sputter target 100 may range from 6:1 to 1:2.

The sputter target of claim 9, wherein the ratio of Pt:Cr may increase radially from a centre to an outer region of the sputter target. Alternatively, the ratio of Pt:Cr may decrease radially from a centre to an outer region of the sputter target.

Proportion of X in the sputter target 100 may range from 2% to 15%.

The proportion of X may increase radially from a centre to an outer region of the sputter target. Alternatively, the proportion of X may decrease radially from a centre to an outer region of the sputter target.

X may be selected from the group consisting of: Ru, Cu and B.

Anisotropy constant Ku of the sputter target may range from 2×10⁶ erg/cc to 15×10⁶ erg/cc. The anisotropy constant Ku may increase radially from a centre to an outer region of the sputter target. Alternatively, the anisotropy constant Ku may decrease radially from a centre to an outer region of the sputter target.

Saturation magnetization of the sputter target 100 may range from 200 emu/cc to 1200 emu/cc.

The saturation magnetization may increase radially from a centre to an outer region of the sputter target. Alternatively, the saturation magnetization may decrease radially from a centre to an outer region of the sputter target.

The layer may comprise a soft under layer and the sputter target may comprise a CoFe—Y.

Proportion of Y in the sputter target may range from 10% to 30%.

The proportion of Y may increase radially from a centre to an outer region of the sputter target. Alternatively, the proportion of Y may decrease radially from a centre to an outer region of the sputter target.

Y may be at least one selected from the group consisting of: Ta, Nb, W, Cr, Mo and B.

Ratio of Fe:Co in the sputter target may range from 1:3 to 3:1.

The ratio of Fe:Co may increase radially from a centre to an outer region of the sputter target. Alternatively, the ratio of Fe:Co may decrease radially from a centre to an outer region of the sputter target.

The sputter target may be configured such that composition of the layer formed by magnetron sputtering of the sputter target varies along a radius of the layer from a centre of the layer to an outer diameter of the layer.

### BRIEF DESCRIPTION OF FIGURES

The present invention will now be described by way of example with reference to the accompanying drawings in which:

FIG. 1 is a schematic illustration of a first embodiment of a sputter target of the present invention with a gradated composition profile from its centre to its outer diameter.

FIG. 2 is a schematic illustration of a second embodiment of a sputter target of the present invention with a 2-step or 3-region composition profile from its centre to its outer diameter.

### DETAILED DESCRIPTION

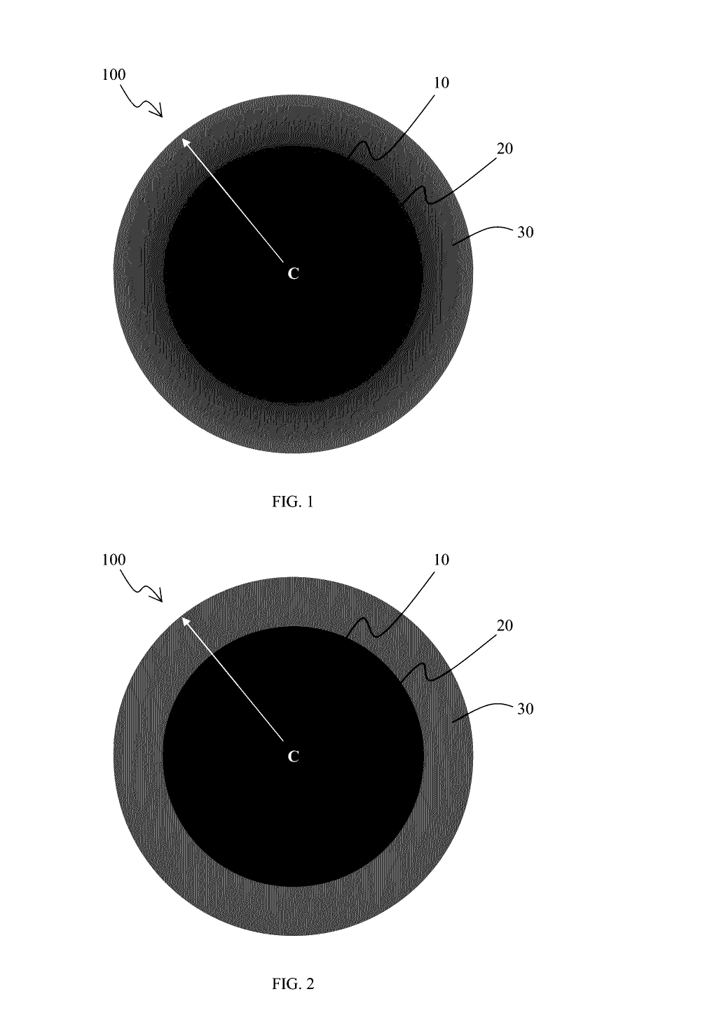

Exemplary embodiments of a sputter target 100 for forming a layer of a perpendicular recording medium by magnetron sputtering will be described below with reference to FIGS. 1 and 2, in which the same reference numerals are used to denote equivalent parts.

The present invention proposes control of the R/W parameters at different zones of a perpendicular recording medium using material composition variation of the sputter target 100 that is used in depositing a layer such as a magnetic film or recording layer or soft under layer SUL of the perpendicular recording medium. Through material selection, several parameters of the sputtered layer can be controlled, namely, saturation magnetization (Ms), anisotropy constant (Ku), inter-granular coupling as well as the grain orientation. The possibility of controlling material of the sputter target 100 at different zones 10, 20, 30 of the sputter target 100 gives much wider scope for BPI and hence areal density improvement at the OD zone of the magnetic recording medium formed by sputtering using the sputter target 100.

In order to realize such a perpendicular recording medium having controlled R/W parameters at different zones, a sputter target 100 with material composition that is varied along its radial direction (as indicated by the white arrow in FIGS. 1 and 2) is provided for use in the sputtering process of forming a layer of the perpendicular magnetic recording medium. Variation of the material composition can be gradated as shown in FIG.1, or variation of the material composition may be in the form of steps radiating from the centre C of the sputter target 100, as shown in FIG. 2, by providing a number of concentric regions 10, 20, 30 in the sputter target 100 wherein each concentric region 10, 20, 30 has a different material composition from the other concentric regions.

The area (size) of each region 10, 20, 30 of the sputter target 100 along its radial direction can be controlled depending on the process as well as the recording medium to be formed. The sputter target 100 may comprise three or more radial regions 10, 20, 30 of different material composition. Process variables such as the sputter chamber dimensions, process conditions and sputter target-magnetron dimensions are some of the considerations to be taken into account during sputtering using the sputter target 10. The exact composition profile of the sputter target 100 will also depend on the actual requirements of the recording medium at each zone and also on dimensions of the perpendicular recording medium to be formed.

In the stepped embodiment of the sputter target 100 as shown in FIG. 2, for a sputter target 100 having a diameter of 170 mm, a first region 10 of the sputter target 100 comprising its centre C preferably extends to a radius of 40 mm, a second region 20 adjacent to and beyond the first region 10 preferably extends from a radius of 40 mm to 60 mm, and the remaining area beyond the second region 10 forms an outermost region or third region 30 of the sputter target 100.

Because requirements for the various media performance parameters are zone specific, for example, the different zones ID-MD-OD have different writability requirements. The present invention can thus provide a means to cater to the zone specific needs of the hard disk drive comprising the recording medium formed using the present invention, as detailed below.

The sputter target 100 may comprise a CoCrPtX-oxide for forming a recording layer of the perpendicular recording medium, where X can be elements like Ru, Cu, B or the like. A higher oxide proportion in the granular recording layers can improve magnetic grain isolation. This in turn can reduce the cluster size and enhance the signal to noise ratio—providing higher areal density capacity. Proportion of oxide in the sputter target 100 of the present invention can thus be configured to range from 5% to 25%, and to vary radially across the sputter target 100 to either increase or decrease radially from the centre C to the outer region 30 of the sputter target 100 (as indicated by the white arrow in FIGS. 1 and 2), in order to provide the desired areal density capacity for each zone (ID, MD, OD) of the medium to formed using the sputter target 100.

For example, proportion of oxide in the sputter target 100 may increase radially along the sputter target 100 from the first region 10 to the third region 30 of the sputter target 100, such that proportion of oxide in the first region 10 is less than proportion of oxide in the second region 20, and proportion of oxide in the second region 20 is less than proportion of oxide in the third region 30. Alternatively, proportion of oxide may decrease radially along the sputter target 100 from the first region 10 to the third region 30 of the sputter target 100, such that proportion of oxide in the first region 10 is greater than proportion of oxide in the second region 20, and proportion of oxide in the second region 20 is greater than proportion of oxide in the third region 30.

As mentioned above, the sputter target 100 may comprise CoCrPtX-oxide, or the sputter target 100 may alternatively comprise CoCrPtX for forming a recording layer of the perpendicular recording medium. Ratio of Pt:Cr in the sputter target 100 ranges from 6:1 1:2. Ratio of Pt:Cr in the sputter target 100 also varies radially across the sputter target 100, and may either increase or decrease radially from the centre C to the outer region 30 of the sputter target 100 (as indicated by the white arrow in FIGS. 1 and 2).

Proportion of X in the sputter target 100 comprising CoCrPtX-oxide or CoCrPtX for forming a recording layer of the perpendicular recording medium ranges from 2% to 15%. Proportion of X in the sputter target also varies radially across the sputter target 100, and may either increase or decrease radially from the centre C to the outer region 30 of the sputter target 100 (as in indicated by the white arrow in FIGS. 1 and 2).

A higher anisotropy constant Ku for the granular layers can provide a greater thermal stability and can improve adjacent track interference (ATI) and far track interference (FTI) performance. Anisotropy constant Ku in the CoCrPtX-oxide or CoCrPtX sputter target 100 for forming a recording layer of the perpendicular recording medium can thus be configured to range from 2×10⁶ to 15×10⁶ erg/cc, and to vary radially across the sputter target 100, in order to provide the desired thermal stability, ATI and FTI for the different zones ID, MD, OD of the layer to be formed using the sputter target 100. For example, Ku may either increase or decrease radially from the centre C to the outer region 30 of the sputter target 100 (as indicated by the white arrow in FIGS. 1 and 2).

Saturation magnetization (Ms) of the sputter target 100 comprising CoCrPtX for forming a recording layer of the perpendicular recording medium ranges from 200 emu/cc to 1200 emu/cc. Ms also varies radially across the sputter target 100, and may either increase or decrease radially from the centre C to the outer region 30 of the sputter target 100 (as indicated by the white arrow in FIGS. 1 and 2).

Where the sputter target 100 is used for forming a soft under layer (SUL) of the perpendicular recording medium, saturation magnetization (Ms) of the sputter target 100 also ranges from 200 to 1200 emu/cc. A higher saturation magnetization (Ms) for the SUL and a capping layer of the medium can enhance the writability, while a lower Ms can reduce the writability. Lower Ms of the capping layer can also be useful in improving cross-track performance like ATI and FTI. Thus, Ms is also configured to vary radially across the sputter target 100 for forming the soft under layer (SUL), and may either increase or decrease radially from the centre C to the outer region 30 of the sputter target 100 (as indicated by the white arrow in FIGS. 1 and 2), in order to suit the desired writability, ATI and FTI of the different zones ID, MD, OD. Notably, with an AFC-Ru layer between the SUL, an SUL material having a lower Ms can improve the recording media writability.

When used for forming a soft under layer (SUL) of the perpendicular recording medium, the sputter target 100 may comprise CoFe—Y wherein Y can be Ta, Nb, W, Cr, Mo, B or a combination of these elements. Proportion of Y ranges from 10% to 30%, while ratio of Fe:Co ranges from 1:3 to 3:1. The proportion of Y as well as the ratio of Fe/Co also individually vary radially across the sputter target 100 for forming the soft under layer (SUL), and may either increase or decrease radially from the centre C to the outer region 30 of the sputter target 100 (as indicated by the white arrow in FIGS. 1 and 2).

As mentioned above, performance of the OD zone is critical because its percentage area is higher than the inner zones, however, head skew as well as higher linear velocity cause poorer performance of the OD zone relative to the MD zone when composition of both zones are the same. To overcome this, in the present invention, the OD zone is given different treatment than the MD zone, by varying the composition of the sputter target 100 along its radius and using the sputter target 100 to form one or more layers (e.g. the recording layer or the SUL) of the perpendicular recording medium by sputter deposition, so that the layer(s) formed also has a varied composition along its radius that corresponds to the variation of composition in the sputter target 100. Through a combination of SUL material, cap layer material, granular oxide composition and anisotropy (Ku or Hk) variations at the OD zone as achieved using the sputter target 100 of the present invention, some recovery in ADC (BPI) performance of the OD zone may thus be obtained.

Whilst there has been described in the foregoing description exemplary embodiments of the present invention, it will be understood by those skilled in the technology concerned that many variations in details of design, construction and/or operation may be made without departing from the present invention. For example, while variation in composition of the sputter target has been described in the examples above as either increasing or decreasing radially, other forms of radial variation in the composition of the sputter target may be configured according to a desired composition of a layer of the medium to be formed by sputtering using the sputter target.

1. A sputter target for forming a layer of a perpendicular recording medium by magnetron sputtering, wherein material composition of the sputter target is varied along a radius of the sputter target from a centre of the sputter target to an outer diameter of the sputter target.

2. The sputter target of claim 1, wherein material composition of the sputter target is varied by gradation of the material composition.

3. The sputter target of claim 1, wherein material composition of the sputter target is varied by providing a number of concentric regions in the sputter target wherein each concentric region has a different material composition from other concentric regions in the number of concentric regions.

4. The sputter target of claim 3, wherein the sputter target has a diameter of 170 mm, a first region of the sputter target comprising its centre extends to a radius of 40 mm, a second region adjacent to and beyond the first region extends from a radius of 40 mm to 60 mm, and a remaining area of the sputter target beyond the second region forms a third region of the sputter target.

5. The sputter target of claim 1, wherein the layer comprises a recording layer and the sputter target comprises one of: a CoCrPtX-oxide and a CoCrPtX.

6. The sputter target of claim 5, wherein the sputter target comprises the CoCrPtX-oxide and proportion of the oxide in the sputter target ranges from 5% to 25%.

7. The sputter target of claim 6, wherein proportion of the oxide increases radially from a centre to an outer region of the sputter target.

8. The sputter target of claim 6, wherein proportion of the oxide decreases radially from a centre to an outer region of the sputter target.

9. The sputter target of claim 5, wherein ratio of Pt:Cr in the sputter target 100 ranges from 6:1 to 1:2.

10. The sputter target of claim 9, wherein the ratio of Pt:Cr increases radially from a centre to an outer region of the sputter target.

11. The sputter target of claim 9, wherein the ratio of Pt:Cr decreases radially from a centre to an outer region of the sputter target.

12. The sputter target of claim 5, wherein proportion of X in the sputter target 100 ranges from 2% to 15%.

13. The sputter target of claim 12, wherein the proportion of X increases radially from a centre to an outer region of the sputter target.

14. The sputter target of claim 12, wherein the proportion of X decreases radially from a centre to an outer region of the sputter target.

15. The sputter target of claim 12, wherein X is selected from the group consisting of: Ru, Cu and B.

16. The sputter target of claim 5, wherein anisotropy constant Ku of the sputter target ranges from 2×10⁶ erg/cc to 15×10⁶ erg/cc.

17. The sputter target of claim 16, wherein the anisotropy constant Ku increases radially from a centre to an outer region of the sputter target.

18. The sputter target of claim 16, wherein the anisotropy constant Ku decreases radially from a centre to an outer region of the sputter target.

19. The sputter target of claim 5, wherein saturation magnetization of the sputter target 100 ranges from 200 emu/cc to 1200 emu/cc.

20. The sputter target of claim 19, wherein the saturation magnetization increases radially from a centre to an outer region of the sputter target.

21. The sputter target of claim 19, wherein the saturation magnetization decreases radially from a centre to an outer region of the sputter target.

22. The sputter target of claim 1, wherein the layer comprises a soft under layer and the sputter target comprises a CoFe—Y.

23. The sputter target of claim 22, wherein proportion of Y in the sputter target ranges from 10% to 30%.

24. The sputter target of claim 23, wherein the proportion of Y increases radially from a centre to an outer region of the sputter target.

25. The sputter target of claim 23, wherein the proportion of Y decreases radially from a centre to an outer region of the sputter target.

26. The sputter target of claim 23, wherein Y is at least one selected from the group consisting of: Ta, Nb, W, Cr, Mo and B.

27. The sputter target of claim 22, wherein ratio of Fe:Co in the sputter target ranges from 1:3 to 3:1.

28. The sputter target of claim 27, wherein the ratio of Fe:Co increases radially from a centre to an outer region of the sputter target.

29. The sputter target of claim 27, wherein the ratio of Fe:Co decreases radially from a centre to an outer region of the sputter target.

30. The sputter target of claim 22 wherein saturation magnetization of the sputter target 100 ranges from 200 emu/cc to 1200 emu/cc.

31. The sputter target of claim 30, wherein the saturation magnetization increases radially from a centre to an outer region of the sputter target.

32. The sputter target of claim 30, wherein the saturation magnetization decreases radially from a centre to an outer region of the sputter target.

33. The sputter target of claim 1, the sputter target configured such that composition of the layer formed by magnetron sputtering of the sputter target varies along a radius of the layer from a centre of the layer to an outer diameter of the layer.
